(19) United States
(12) Patent Application Publication
(10) Pub. No.: US 2026/0130150 A1
(43) Pub. Date: May 7, 2026

(54) METHOD OF MANUFACTURING SEMICONDUCTOR DEVICE AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Riku KATAMAWARI, Nonoichi Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/035,439

(22) Filed: Jan. 23, 2025

(30) Foreign Application Priority Data
Sep. 20, 2024 (JP) 2024-164291

(51) Int. Cl. H01L 21/304; H10D 62/10

(52) U.S. Cl. CPC H10P 52/00; H10D 62/124

(57) ABSTRACT

A method of manufacturing a semiconductor device according to an embodiment includes: forming a plurality of semiconductor elements in a device region of a first main surface of a semiconductor wafer; and forming a rim on the semiconductor wafer, the rim surrounding the plurality of semiconductor elements and having a rigidity in a Y-axis direction that is higher than a rigidity in an X-axis direction when a first warpage amount of the semiconductor wafer in the X-axis direction is smaller than a second warpage amount of the semiconductor wafer in the Y-axis direction.

### CROSS-REFERENCE TO RELATED APPLICATIONS

This application is based upon and claims the benefit of priority from Japanese Patent Application No. 2024-164291, filed on Sep. 20, 2024, the entire contents of which are incorporated herein by reference.

### FIELD

Embodiments described herein relate generally to a method of manufacturing a semiconductor device and a semiconductor device.

### BACKGROUND

There are known semiconductor elements such as MOSFETs (Metal-Oxide-Semiconductor Field-Effect Transistors) and IGBTs (Insulated Gate Bipolar Transistors) as so-called power semiconductors. Such semiconductor elements are manufactured, for example, through the following process.

Various processes such as photolithography, ion implantation, and etching are performed to form a plurality of semiconductor elements on the front surface side of a semiconductor wafer. Then, the back surface of the semiconductor wafer is ground and thinned through back grinding or the like. After that, a metal film (electrode) is formed on the back surface of the semiconductor wafer by sputtering. Finally, a dicing process is performed to obtain a plurality of semiconductor chips including semiconductor elements.

As described above, various processes up to the dicing process are performed on each semiconductor wafer. However, the semiconductor wafer may warp in a specific direction due to the surface structure of the semiconductor element formed on the semiconductor wafer. In such a case, difficulty in the process flow increases.

### BRIEF DESCRIPTION OF THE DRAWINGS

FIG. 1A is a flowchart for describing a method of manufacturing a semiconductor device according to an embodiment (advance measurement of a wafer warpage amount);

FIG. 1B is a flowchart for describing a method of manufacturing a semiconductor device according to the embodiment;

FIG. 2 is a plan view of a semiconductor device (semiconductor wafer) according to a first embodiment;

FIG. 3A is a cross sectional view taken along a line X-X in FIG. 2;

FIG. 3B is a cross sectional view taken along a line Y-Y in FIG. 2;

FIG. 4 is a diagram for describing an action and effect of the first embodiment;

FIG. 5 is a diagram for describing a method of manufacturing a semiconductor device according to the first embodiment;

FIG. 6 is a diagram for describing operation control of a spindle in manufacturing a semiconductor device according to the first embodiment;

FIG. 7 is a plan view of a semiconductor device (semiconductor wafer) according to a modification of the first embodiment;

FIG. 8A is a cross sectional view taken along a line X-X in FIG. 7;

FIG. 8B is a cross sectional view taken along a line Y-Y in FIG. 7;

FIG. 9 is a diagram for describing operation control of the spindle in manufacturing a semiconductor device according to a modification of the first embodiment;

FIG. 10 is a plan view of a semiconductor device (semiconductor wafer) according to a second embodiment;

FIG. 11A is a cross sectional view taken along a line I-I in FIG. 10;

FIG. 11B is a cross sectional view taken along a line II-II in FIG. 10;

FIG. 12 is a plan view of a semiconductor device (semiconductor wafer) according to a third embodiment;

FIG. 13A is a cross sectional view taken along a line X-X in FIG. 12;

FIG. 13B is a cross sectional view taken along a line Y-Y in FIG. 12;

FIG. 14 is a diagram for describing a method of manufacturing a semiconductor device according to a third embodiment;

FIG. 15 is a diagram for describing operation control of a blade in manufacturing a semiconductor device according to the third embodiment;

FIG. 16 is a plan view of a semiconductor device (semiconductor wafer) according to a fourth embodiment;

FIG. 17A is a cross sectional view taken along a line X-X in FIG. 16;

FIG. 17B is a cross sectional view taken along a line Y-Y in FIG. 16;

FIG. 18 is a plan view of a semiconductor device (semiconductor wafer) according to a fifth embodiment;

FIG. 19A is a cross sectional view taken along a line X-X in FIG. 18; and

FIG. 19B is a cross sectional view taken along a line Y-Y in FIG. 18.

### DETAILED DESCRIPTION

A method of manufacturing a semiconductor device according to an embodiment includes: forming a plurality of semiconductor elements in a device region of a first main surface of a semiconductor wafer; and forming a rim on the semiconductor wafer, the rim surrounding the plurality of semiconductor elements and having a rigidity in a Y-axis direction that is higher than a rigidity in an X-axis direction when a first warpage amount of the semiconductor wafer in the X-axis direction is smaller than a second warpage amount of the semiconductor wafer in the Y-axis direction.

The semiconductor device according to a first aspect includes: a central portion including a device region in which a plurality of semiconductor elements are formed; and a rim, thicker than the central portion, configured to surround the central portion, in which a width of the rim in an X-axis direction is greater than a width of the rim in a Y-axis direction.

The semiconductor device according to a second aspect includes: a central portion including a device region in which a plurality of semiconductor elements are formed; and a rim, thicker than the central portion, configured to surround the central portion, in which the rim has a thickness at a portion intersecting with an X-axis that is greater than a thickness at a portion intersecting with a Y-axis.

An embodiment according to the present disclosure will be described below with reference to the drawings. Note that the embodiment does not limit the present disclosure. The drawings are schematic or conceptual, and ratios between parts are not necessarily the same as the actual ones. In the specification and drawings, elements similar to those previously described with reference to the previous drawings are given the same reference numerals and characters, and detailed description is omitted as appropriate.

### Method of Manufacturing a Semiconductor Device

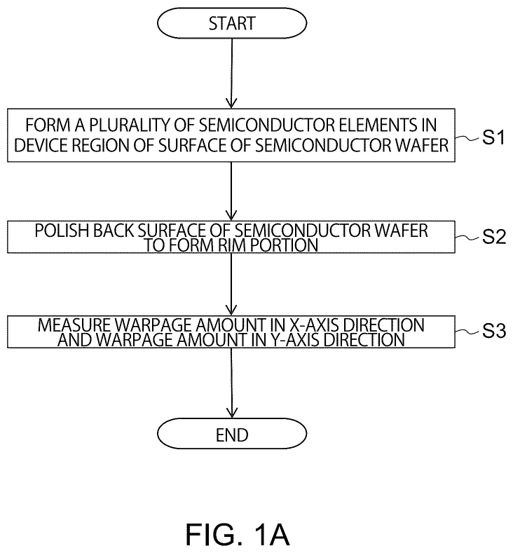

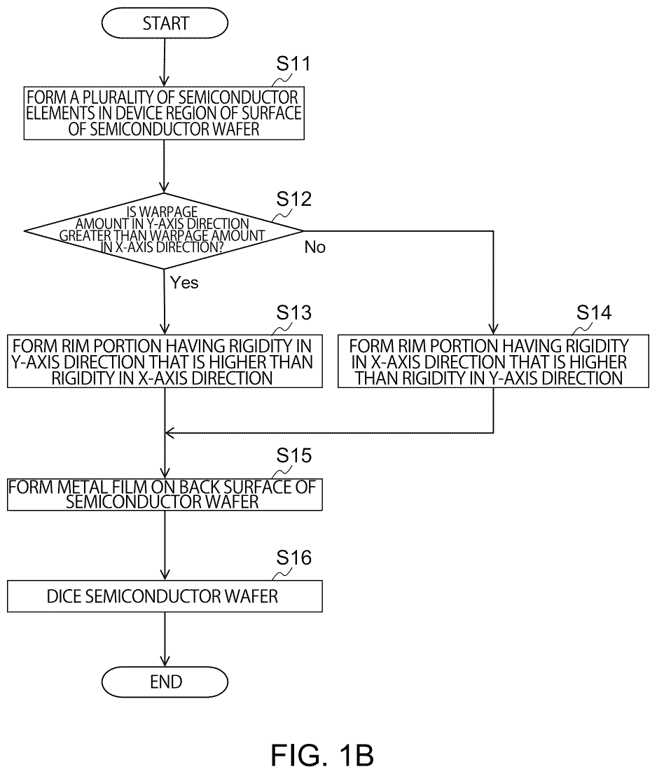

The following describes an example of a method of manufacturing a semiconductor device according to an embodiment with reference to FIGS. 1A and 1B. FIG. 1A shows an example of a method of measuring the warpage amount of a semiconductor wafer in advance. FIG. 1B shows an example of a method of manufacturing a semiconductor device from a semiconductor wafer of the same type based on the measured warpage amount.
Step S1: Form a plurality of semiconductor elements in a device region on the surface (first main surface) of a semiconductor wafer. The device region corresponds to a device region D of a semiconductor device 1 described later. The semiconductor element is, for example, a MOSFET in which a gate electrode and a field plate electrode are disposed in an insulating film buried in a trench of a semiconductor layer (hereinafter, referred to as an FP trench MOS). This FP trench MOS is a MOSFET in which: an insulating film is buried in a trench formed in a semiconductor layer; and a gate electrode and a field plate electrode are disposed in this insulating film. In this way, the semiconductor element of this example has a trench structure extending in a predetermined direction (for example, an X-axis direction or a Y-axis direction). The type of semiconductor element is not particularly limited, and may be, for example, an IGBT, a diode, a thyristor.
Step S2: Grind the back surface (second main surface) of the semiconductor wafer to form a rim. The second main surface is located on the side opposite to the first main surface. At least, a region of the second main surface is ground, the region corresponding to a portion where device region is formed on the first main surface. The semiconductor wafer is ground through back-grinding. The ground thin region of the semiconductor wafer becomes a membrane (corresponding to a central portion 2 described later). The rim is an annular rim that surrounds the plurality of semiconductor elements formed in the device region. The thickness of the rim is thicker than that of the device region. The rim formed in this step has a uniform width. In other words, the rim of the semiconductor wafer has a constant radial length in the circumferential direction.
Step S3: Measure the warpage amount in the X-axis direction (a first warpage amount) and the Y-axis direction (a second warpage amount) for the semiconductor wafer with the rim formed. The measurement in this step is performed using optical interference method, a laser displacement sensor, laser displacement gauge, or the like. The X-axis direction is the direction of an axis that passes through a predetermined position on the semiconductor wafer. The Y-axis direction is the direction that intersects with the X-axis direction. In this embodiment, the X-axis passes through the center of the semiconductor wafer, and the Y-axis direction is the direction perpendicular to the X-axis direction. In this embodiment, a notch (not shown) is formed on the Y-axis as a mark to indicate the crystal orientation of the semiconductor wafer.

In this manner, the warpage amounts in the X-axis direction and the Y-axis direction are measured for the semiconductor wafer with the plurality of semiconductor elements formed in the device region. When the trench of a semiconductor element (FP trench MOS) extends in the X-axis direction, the warpage amount in the Y-axis direction may be greater than the warpage amount in the X-axis direction. The warpage amount in one of the X-axis direction and the Y-axis direction may be greater, not only due to the trench structure, but also due to the thickness of the metal film (such as source metal) formed on the surface of the semiconductor wafer, the pattern shape and size of the semiconductor element, or various conditions in the manufacturing process of the semiconductor element. According to the study made by the inventor of the present application, if the semiconductor wafer and semiconductor element are the same, the tendency of the warping of the semiconductor wafer is almost the same.

The following describes an example of a method of manufacturing a semiconductor device using a semiconductor wafer of the same type as the semiconductor wafer whose warpage amount has been measured according to the flow shown in FIG. 1B. Note that here, “the same type of semiconductor wafer” means a semiconductor wafer that has at least one of the same material (silicon, silicon carbide, etc.), size (diameter, thickness), shape, model number/product number, and lot as the semiconductor wafer whose warpage amount has been measured.
Step S11: Form a plurality of semiconductor elements in a device region on the surface of a semiconductor wafer of the same type as the semiconductor wafer whose warpage amount has been measured. The material of the semiconductor wafer is not particularly limited, and may be silicon, for example. The semiconductor elements formed in this step are the same as the plurality of semiconductor elements formed in step S1. Here, “the same” means that the type, structure, and manufacturing process of the semiconductor elements are the same.
Step S12: Measure the warpage amount in the X-axis direction and Y-axis direction for the semiconductor wafer on which the plurality of semiconductor elements were formed in step S11, and determine whether the warpage amount in the Y-axis direction is greater than the warpage amount in the X-axis direction. If the warpage amount in the Y-axis direction is greater than the warpage amount in the X-axis direction (i.e., if the warpage amount in the X-axis direction is less than the warpage amount in the Y-axis direction), the process proceeds to step S13; otherwise, the process proceeds to step S14.
Step S13: Form a rim on the semiconductor wafer, the rim surrounding the plurality of semiconductor elements and having a rigidity in the Y-axis direction that is higher than a rigidity in the X-axis direction. The rigidity in the Y-axis direction in the present application means the degree of resistance to deformation of the annular rim in the YZ plane against stress on the semiconductor wafer (more specifically, stress generated in the semiconductor wafer due to the surface structure of the semiconductor wafer). Similarly, the rigidity in the X-axis direction means the degree of resistance to deformation of the annular rim in the XZ plane against stress on the semiconductor wafer. Here, the YZ plane is a plane formed by the Y axis and the Z axis perpendicular to the X and Y axes. The XZ plane is a plane formed by the X and Z axes. Specific embodiments of the rim will be described later.
Step S14: Form a rim on the semiconductor wafer, the rim surrounding the plurality of semiconductor elements and having a rigidity in the X-axis direction that is higher than a rigidity in the Y-axis direction. Specific examples will be mentioned in each embodiment described later.
Step S15: Form a metal film (drain electrode, collector electrode, etc.) on the back surface of the semiconductor wafer. There may be a way of performing ion implantation on the back surface of the semiconductor wafer before forming the metal film, to form an n-type semiconductor region (drain region) of a MOSFET or a p-type semiconductor region (collector region) of an IGBT.
Step S16: Dice the semiconductor wafer to separate the plurality of semiconductor elements into individual pieces. Specifically, the back surface of the semiconductor wafer is fixed to a dicing tape, and the semiconductor wafer is cut along the dicing line by a blade (e.g. rotary blade). Then, the semiconductor chips, which are the individual pieces, are removed from the dicing tape.

According to the above-mentioned method of manufacturing a semiconductor device, the warpage amount is measured in advance in the X-axis direction and the Y-axis direction of a semiconductor wafer formed with a uniform rim width. When a semiconductor device is manufactured from the same type of semiconductor wafer, a rim having different rigidity in the X-axis direction and the Y-axis direction is formed based on the warpage amount measurement results. This makes it possible to prevent the semiconductor wafer from warping in a specific direction due to the surface structure of the semiconductor element. This then makes it possible to reduce difficulty in process flow, and to improve the productivity and quality of the semiconductor device.

Note that the above method is merely an example, and various modifications are possible.

For example, step S2 may be omitted. In other words, after step S1, the warpage amount in the X-axis direction and the warpage amount in the Y-axis direction are measured for a semiconductor wafer that has not been subjected to grinding of the back surface. Also in this way, it is possible to know the magnitude relationship between the warpage amount in the X-axis direction and the warpage amount in the Y-axis direction and to perform step S12.

When step S2 is omitted, there may be a way in which: the warpage amount of the semiconductor wafer is measured in step S3; and then a rim of the semiconductor wafer is formed based on the measurement results. In this case, after step S3, step S11 is skipped, and the next step is performed instead of step S12. In other words, based on the measurement results of step S3, a step is performed that determines whether the warpage amount in the Y-axis direction is greater than the warpage amount in the X-axis direction. If the warpage amount in the Y-axis direction is greater than the warpage amount in the X-axis direction, a rim is formed that surrounds the plurality of semiconductor elements and that has a rigidity in the Y-axis direction that is higher than a rigidity in the X-axis direction. Contrarily, if the warpage amount in the Y-axis direction is smaller than the warpage amount in the X-axis direction, a rim is formed that surrounds the plurality of semiconductor elements and that has a rigidity in the X-axis direction that is higher than a rigidity in the Y-axis direction.

It is also possible to estimate the warpage amount in the X-axis and Y-axis directions of a semiconductor wafer based on the type, structure, etc. of a semiconductor device formed on the semiconductor wafer. Such an estimate is made based on the manufacturing experience (accumulation of data, etc.) of semiconductor devices, simulations, etc. A rim may be formed based on an estimated value of the warpage amount of the semiconductor wafer. In this case, steps S1 to S3 are not performed, and in step S12, estimated values are used as the warpage amounts in the X-axis and Y-axis directions. If the estimated warpage amount in the Y-axis direction is greater than the estimated warpage amount in the X-axis direction, a rim is formed that surrounds the plurality of semiconductor elements and that has a rigidity in the Y-axis direction that is higher than a rigidity in the X-axis direction. Contrarily, if the estimated warpage amount in the Y-axis direction is smaller than the estimated warpage amount in the X-axis direction, a rim is formed that surrounds the plurality of semiconductor elements and that has a rigidity in the X-axis direction that is higher than a rigidity in the Y-axis direction.

As described above, the “warpage amount” in step S12 may be an actual measured value or an estimated value. The actual measured value may be a value measured on a semiconductor wafer of the same type as the semiconductor wafer on which the rim is to be formed, or may be a value measured on the semiconductor wafer itself on which the rim is to be formed.

The following describes first to fifth embodiments according to a semiconductor device having a rim with different rigidity in the X-axis direction and the Y-axis direction. Note that the “semiconductor device” mentioned here means a semiconductor wafer on which a plurality of semiconductor elements are formed in the device region.

### First Embodiment

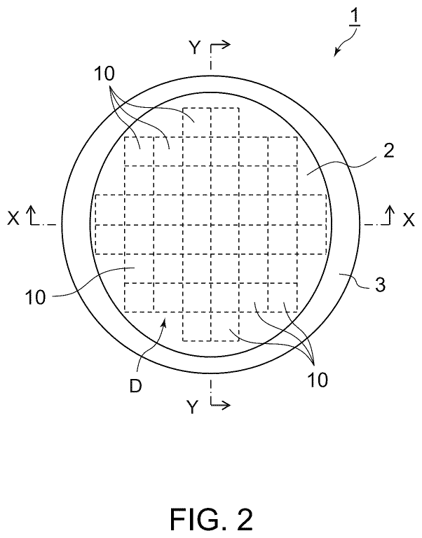

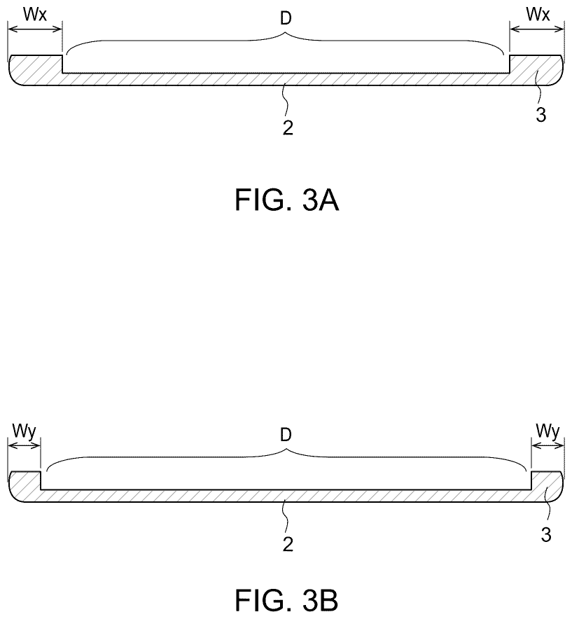

A semiconductor device 1 according to a first embodiment will be described with reference to FIGS. 2, 3A, and 3B. FIG. 2 is a plan view of the semiconductor device 1. FIG. 3A is a cross sectional view taken along a line X-X in FIG. 2, and FIG. 3B is a cross sectional view taken along a line Y-Y in FIG. 2.

The semiconductor device 1 includes a central portion 2 including a device region D, and a rim 3 that surrounds the central portion 2 and is thicker than the central portion 2. A plurality of semiconductor elements 10 are formed in the device region D. The rim 3 is configured integrally with the central portion 2. The rim 3 is made of the same semiconductor material as the central portion 2 (e.g., silicon, silicon carbide, etc.).

The width Wx of the rim 3 is greater than the width Wy of the rim 3. The width Wx is the length (width) of the portion of the rim 3 that intersects with the X-axis passing through the center of the semiconductor device 1, and may be referred to as a “width in the X-axis direction.” The width Wy is the length (width) of the portion of the rim 3 that intersects with the Y-axis passing through the center of the semiconductor device 1 and is perpendicular to the X-axis, and may be referred to as a “width in the Y-axis direction.” In this embodiment, the width of the rim 3 smoothly decreases from width Wx to width Wy in the circumferential direction, and smoothly increases from width Wy to width Wx.

The inner edge shape of the rim 3 in this embodiment (i.e., the shape of the central portion 2) is an ellipse, an oval, or an egg shape. In the example of FIG. 2, the minor axis of the ellipse coincides with the X-axis, and the major axis thereof coincides with the Y-axis.

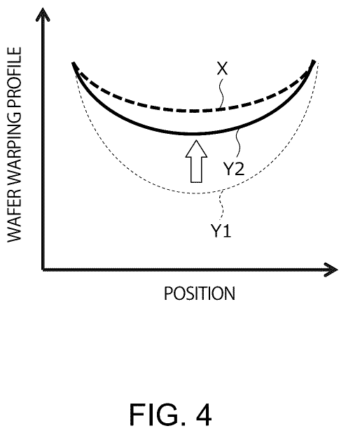

As described above, in the first embodiment, the width Wx is greater than the width Wy, and the rigidity of the rim 3 in the Y-axis direction is therefore higher than the rigidity in the X-axis direction. In FIG. 4, the longitudinal axis represents a wafer warping profile and the horizontal axis represents the position (along the X direction or the Y direction). As the wafer warping profile approaches a flatter shape, the warpage amount of the wafer is considered to decrease. Therefore, as schematically shown in FIG. 4, the warpage amount in the Y-axis direction of the semiconductor device 1, in which the rim 3 is formed (represented by the reference character Y2), is smaller than the warpage amount in the Y-axis direction of the semiconductor device, in which the rim of uniform width is formed (represented by the reference character Y1). As a result, the warpage amount with the rim 3 approaches the warpage amount in the X-axis direction. This makes it possible to prevent the semiconductor device (semiconductor wafer) from warping in a specific direction, and to make the in-plane warping closer to uniform.

In this embodiment, reducing the warpage amount in the Y-axis direction reduces difference between the warpage amount in the X-axis direction and the warpage amount in the Y-axis direction. As another method, the warpage amount in the X-axis direction may be increased to reduce the difference between the warpage amount in the X-axis direction and the warpage amount in the Y-axis direction.

If the warpage amount in the X-axis direction is greater than the warpage amount in the Y-axis direction in the advance measurement of the warpage amount of the wafer, the rim just needs to be configured so as to have a width in the Y-axis direction that is greater than a width in the X-axis direction. For example, in FIG. 2, the ellipse of the inner edge of the rim 3 just needs to be rotated 90 degrees around the center of the semiconductor wafer to form an ellipse in a horizontally elongated shape.

### Method of Forming the Rim According to the Semiconductor Device 1

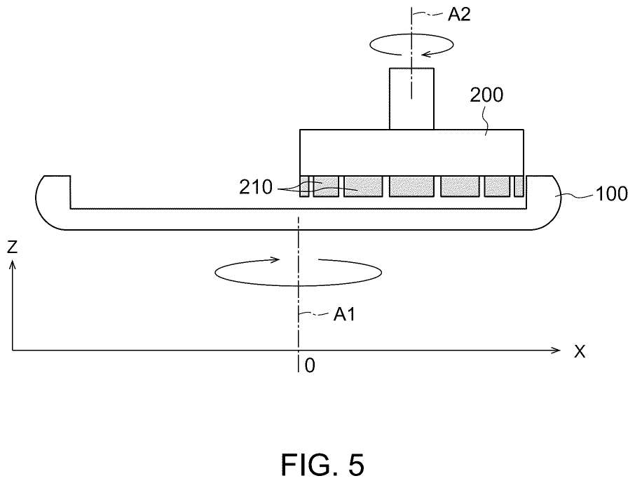

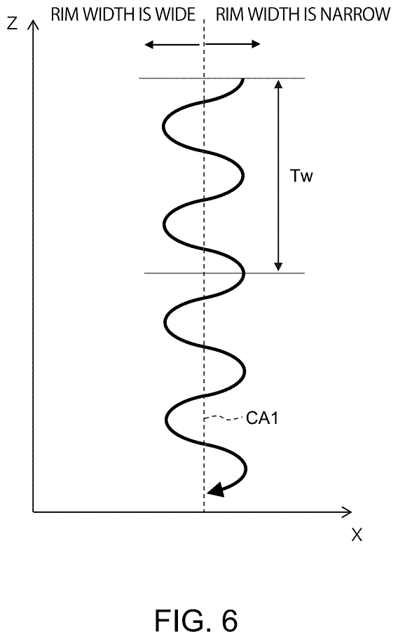

Here, the following describes an example of a method of manufacturing the rim 3 according to the first embodiment with reference to FIG. 5 and FIG. 6. FIG. 5 is a diagram showing how the semiconductor wafer is ground by a spindle, and FIG. 6 is a diagram for describing the operation control of the spindle. Note that FIG. 6 focuses on the right rim (i.e., the side where X>0) of the left and right rims shown in FIG. 5.

Grindstones 210 are attached to the under surface of the spindle 200. The semiconductor wafer 100 is fixed to a rotating table (not shown) with the back surface facing up. When the semiconductor wafer 100 is ground, the semiconductor wafer 100 rotates together with the rotating table around the rotation axis A1, and the spindle 200 rotates around the rotation axis A2. The position of the spindle 200 (grindstones 210) is controlled in the X-axis direction and the Z-axis direction (vertical direction) by an external control device (not shown). This controlled spindle grinds the area of the back surface of the semiconductor wafer 100 that corresponds to the device region D. The region including the device region D may also be ground.

Here, the position control of the spindle 200 will be described in detail with reference to FIG. 6. As shown in FIG. 6, the spindle 200 is controlled to move in the negative direction of the Z axis while periodically moving in the positive direction or negative direction of the X axis around the central axis CA1. Note that since the central axis CA1 is parallel to the Z axis, the inner wall of the rim 3 is substantially perpendicular to the surface of the central portion 2.

In FIG. 6, the period Tw is the time in which the semiconductor wafer 100 rotates once. In the period Tw, the spindle 200 moves alternately (vibrates) in the positive direction or negative direction of the X-axis for two periods along a sine curve. This forms a rim 3 having a width in the X-axis direction that is greater than a width in the Y-axis direction. As shown in FIG. 2, there is formed a rim 3 whose width changes smoothly from width Wx to width Wy (or from width Wy to width Wx) in the circumferential direction. Note that the spindle 200 is not limited to moving along a sine curve, and may move along a waveform such as a triangular wave. Generally speaking, the spindle 200 may move along a waveform that repeats two maximums and two minimums in the X-axis direction in the period Tw.

### Modification of the First Embodiment

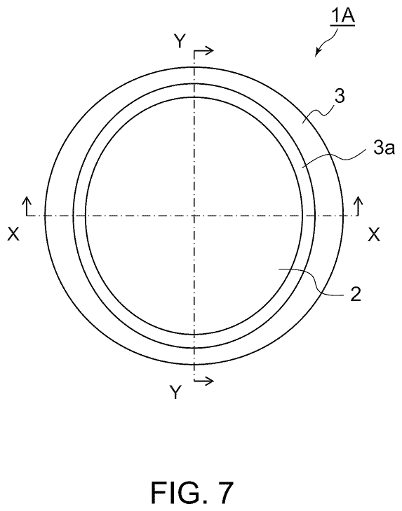

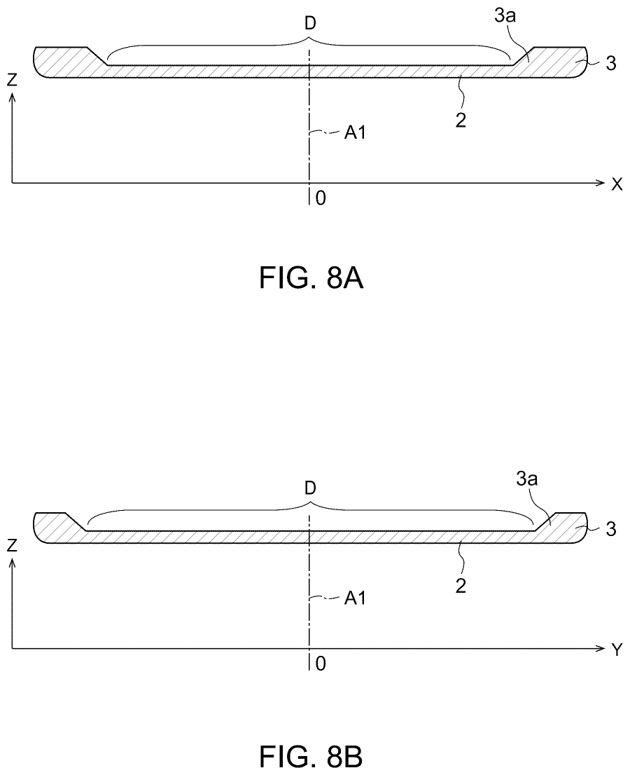

A modification of the first embodiment will be described with reference to FIGS. 7, 8A, and 8B. FIG. 7 is a plan view of a semiconductor device 1A according to this modification. FIG. 8A is a cross sectional view taken along a line X-X in FIG. 7, and FIG. 8B is a cross sectional view taken along a line Y-Y in FIG. 7. Here, a plurality of semiconductor elements 10 are not shown in FIG. 7.

The semiconductor device 1A includes a central portion 2 including a device region D, a rim 3 that surrounds the central portion 2 and is thicker than the central portion 2, and a slope 3a provided inside the rim 3. The slope 3a connects the rim 3 and the central portion 2. The surface of the slope 3a intersects obliquely with the surfaces of the central portion 2 and the rim 3. In this example, the slope 3a has a uniform width, but it may have a non-uniform width.

### Method of Forming the Rim According to the Semiconductor Device 1A

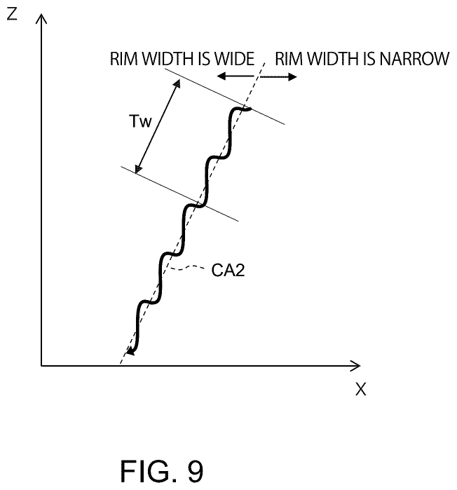

The following describes an example of a method of manufacturing the rim 3 according to this modification with reference to FIG. 9. FIG. 9 is a diagram for describing the operation control of the spindle. Note that FIG. 9 focuses on the right rim (i.e., the side where X>0) of the left and right rims shown in FIG. 8A. However, the operation control of the spindle in the XZ plane shown in FIG. 9 may be discussed in the YZ plane by focusing on the right rim (i.e., the side where Y>0) of the left and right rims shown in FIG. 8B.

As shown in FIG. 9, the spindle 200 moves in the negative direction of the Z axis while periodically moving in the positive direction or negative direction of the X axis around the central axis CA2. Since the central axis CA2 is inclined with respect to the Z axis, a slope 3a is formed. In this modification, a region of the back surface of the semiconductor wafer 100 is ground. The region includes an area corresponding to a portion where the device region D is formed on the front surface of the semiconductor wafer 100.

### Second Embodiment

Next, a second embodiment will be described. In the second embodiment, a slope of non-uniform width is provided to form a rim having a rigidity in the Y-axis direction that is higher than a rigidity in the X-axis direction.

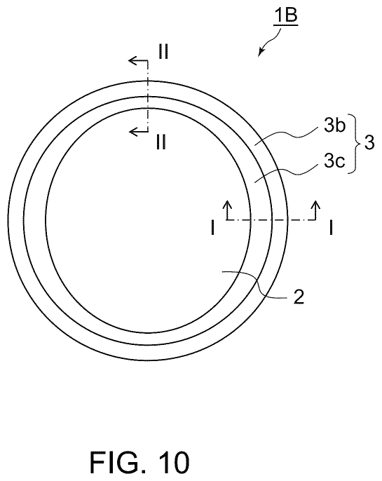

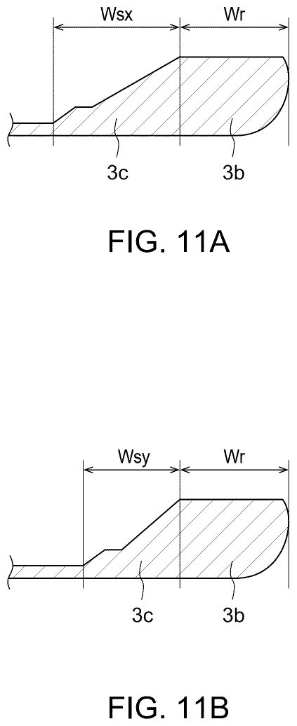

A semiconductor device 1B according to the second embodiment will be described with reference to FIGS. 10, 11A, and 11B. FIG. 10 is a plan view of the semiconductor device 1B. FIG. 11A is a cross sectional view taken along a line I-I in FIG. 10, and FIG. 11B is a cross sectional view taken along a line II-II in FIG. 10. Note that a plurality of semiconductor elements 10 are not shown in FIG. 10.

The semiconductor device 1B includes a central portion 2 including a device region D, and a rim 3 that surrounds the central portion 2 and is thicker than the central portion 2.

The rim 3 according to the second embodiment has a uniform rim 3b having a uniform width, and a slope 3c provided inside the uniform rim 3b. The slope 3c has a width in the X-axis direction that is greater than a width in the Y-axis direction. The width of the slope 3c changes smoothly in the circumferential direction. The inner edge shape of the slope 3c is an ellipse, an oval, or an egg shape. In the example of FIG. 10, the minor axis of the ellipse coincides with the X-axis, and the major axis coincides with the Y-axis. As shown in FIGS. 11A and 11B, the uniform rim 3b has a width Wr in both the X-axis direction and the Y-axis direction, while the slope 3c has a width Wsx in the X-axis direction that is greater than a width Wsy in the Y-axis direction. The width of the slope is changed by varying the slope angle.

As described above, in the second embodiment, the width of the slope in the X-axis direction is made different from that in the Y-axis direction, thereby forming a rim having a rigidity in the Y-axis direction that is greater than a rigidity in the X-axis direction.

### Third Embodiment

Next, a third embodiment will be described. In the third embodiment, the thickness of the rim having a uniform width is varied in the circumferential direction, thereby forming a rim having a rigidity in the Y-axis direction that is higher than a rigidity in the X-axis direction.

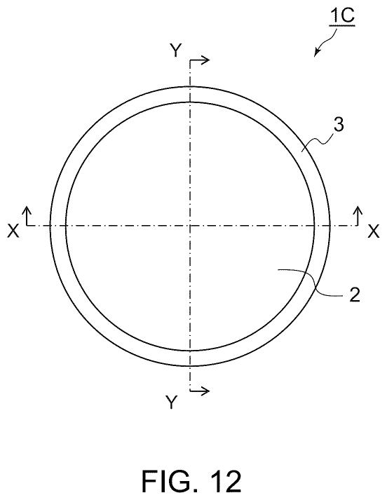

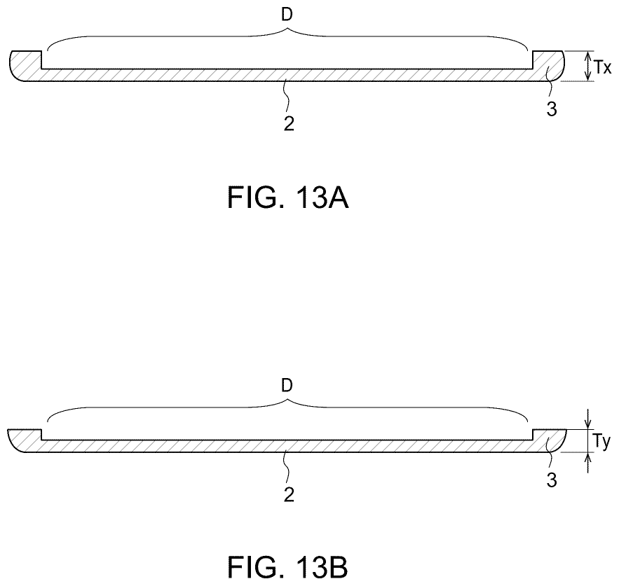

A semiconductor device 1C according to the third embodiment will be described with reference to FIGS. 12, 13A, and 13B. FIG. 12 is a plan view of the semiconductor device 1C. FIG. 13A is a cross sectional view taken along a line X-X in FIG. 12, and FIG. 13B is a cross sectional view taken along a line Y-Y in FIG. 12. Note that a plurality of semiconductor elements 10 are not shown in FIG. 12.

The semiconductor device 1C includes a central portion 2 including a device region D in which a plurality of semiconductor elements are formed, and a rim 3 that surrounds the central portion 2 and is thicker than the central portion 2.

The rim 3 according to the third embodiment has a uniform width. The rim 3 has a thickness in the X-axis direction that is greater than a thickness in the Y-axis direction. As shown in FIGS. 13A and 13B, the rim 3 has a thickness Tx in the X-axis direction that is greater than a thickness Ty in the Y-axis direction. Here, the thickness Tx is the thickness of the rim 3 at the portion intersecting with the X-axis passing through the center of the semiconductor device 1, and may be referred to as a “thickness in the X-axis direction”. The thickness Ty is the thickness of the rim 3 at the portion intersecting with the Y-axis passing through the center of the semiconductor device 1 and perpendicular to the X-axis, and may be referred to as a “thickness in the Y-axis direction”.

As described above, in the third embodiment, the thickness of the rim in the X-axis direction is made different from that in the Y-axis direction, thereby forming a rim having a rigidity in the Y-axis direction that is higher than a rigidity in the X-axis direction.

Note that the rim according to the third embodiment is not limited to having a uniform width, and may have different width in the X-axis direction and the Y-axis direction, as in the first embodiment.

### Method of Forming the Rim According to the Semiconductor Device 1C

The following describes am example of a method of manufacturing the rim 3 according to the third embodiment.

First, in the back surface of the semiconductor wafer, an area is ground that corresponds to the device region, to form a provisional rim having a uniform width. The provisional rim corresponds to the rim formed in step S2 described above. The provisional rim is not limited to having a uniform width, and may be formed so as to have a width in the X-axis direction different from a width in the Y-axis direction, as in the first embodiment.

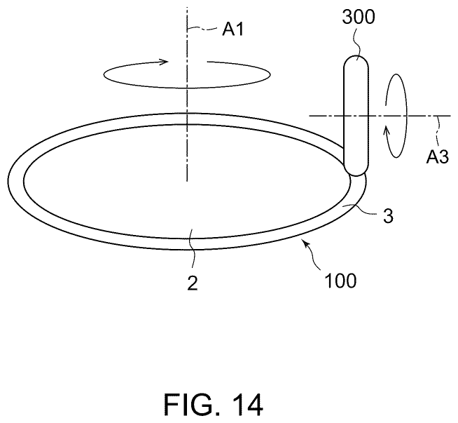

Next, as shown in FIG. 14, the upper surface of the provisional rim is ground to form a rim having a thickness in the X-axis direction that is greater than a thickness in the Y-axis direction. The provisional rim is ground using a blade 300 that rotates around the rotation axis A3. With the semiconductor wafer 100 rotating around the rotation axis A1, the blade 300 is applied to the upper surface of the provisional rim to adjust its thickness.

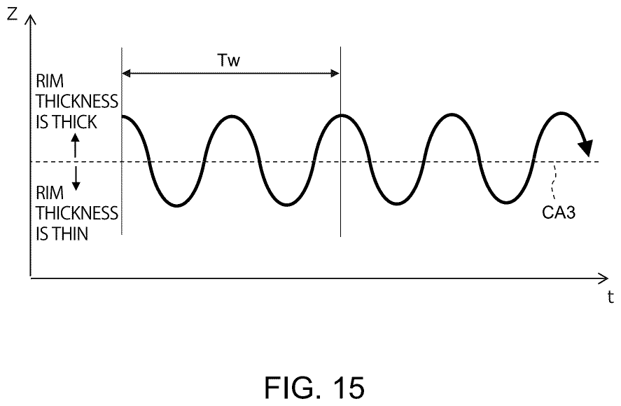

Specifically, as shown in FIG. 15, the blade 300 moves periodically in the positive direction or negative direction of the Z axis around the central axis CA3. In a period Tw in which the semiconductor wafer 100 rotates once, the blade 300 moves alternately (vibrates) in the positive direction or negative direction of the Z axis for two periods along a sine curve. This can cause the thickness to be maximum in the X-axis direction and to be minimum in the Y-axis direction, forming a rim whose thickness changes smoothly in the circumferential direction. Note that the blade 300 is not limited to moving along a sine curve, and may move along a waveform such as a triangular wave. Generally speaking, the blade 300 just needs to move along a waveform that repeats two maximums and two minimums in the X-axis direction in the period Tw.

### Fourth Embodiment

Next, a fourth embodiment will be described. In the fourth embodiment, a reinforcement member is fixed to a wafer circumference (circumferential edge portion of a semiconductor wafer) having the same thickness as the central portion, thereby forming a rim that has a rigidity in the Y-axis direction that is higher than a rigidity in the X-axis direction.

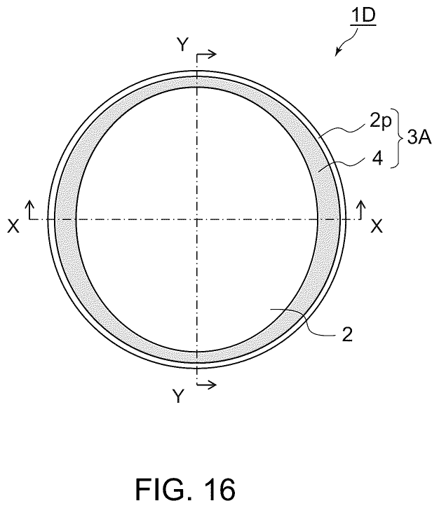

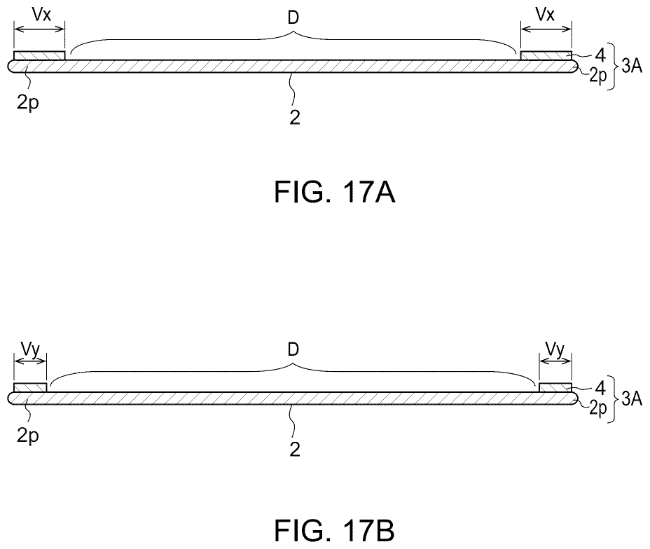

A semiconductor device 1D according to a fourth embodiment will be described with reference to FIGS. 16, 17A, and 17B. FIG. 16 is a plan view of the semiconductor device 1D. FIG. 17A is a cross sectional view taken along a line X-X in FIG. 16, and FIG. 17B is a cross sectional view taken along a line Y-Y in FIG. 16. Note that a plurality of semiconductor elements 10 are not shown in FIG. 16.

The semiconductor device 1D includes a central portion 2 including a device region D in which a plurality of semiconductor elements are formed, and a rim 3A. The rim 3A includes a wafer circumference 2p surrounding the central portion 2, and a reinforcement member 4 fixed onto the wafer circumference 2p. In this embodiment, the wafer circumference 2p has the same thickness as the central portion 2.

The reinforcement member 4 is a ring-shaped member having a width in the X-axis direction that is greater than a width in the Y-axis direction. The inner edge shape of the reinforcement member 4 is an ellipse, an oval, or an egg shape. In the example of FIG. 16, the minor axis of the ellipse coincides with the X-axis, and the major axis coincides with the Y-axis. The material of the reinforcement member 4 is not particularly limited, but may be, for example, glass, resin, or metal.

The reinforcement member 4 is fixed to the wafer circumference 2p with an adhesive. For example, an acrylic resin adhesive is used. In addition, other resin adhesives, such as polyethylene, polypropylene, polyamide, polyvinyl alcohol, triacetyl cellulose, methacrylic resin, polystyrene, and polyvinylidene fluoride, may also be used. The reinforcement member 4 is not limited to being fixed with an adhesive, and may be fixed to the wafer circumference 2p using a double-sided adhesive tape. Alternatively, the reinforcement member 4 may be fixed to the wafer circumference 2p using a low melting point metal or alloy (including, for example, tin (Sn) or bismuth (Bi)).

As described above, in the fourth embodiment, the reinforcement member 4, which has different width in the X-axis direction and the Y-axis direction, is provided on the wafer circumference 2p, thereby forming a rim 3A having a rigidity in the Y-axis direction that is higher than a rigidity in the X-axis direction. Note that the reinforcement member 4 is not limited to being fixed to the wafer circumference 2p having the same thickness as the central portion 2. In other words, the reinforcement member 4 may be fixed to the wafer circumference that is thicker than the central portion 2, which is formed by grinding the back surface of the semiconductor wafer, thereby forming the rim 3A of this embodiment.

### Method of Forming the Rim According to the Semiconductor Device 1D

The following describes an example of a method of manufacturing the rim 3A according to the fourth embodiment.

First, the back surface of the semiconductor wafer on which a plurality of semiconductor elements are formed is ground over its entire surface. Then, the reinforcement member 4 is fixed to the wafer circumference 2p using an adhesive or the like. This forms a rim having a rigidity in the Y-axis direction that is higher than a rigidity in the X-axis direction.

There may be a way of grinding the back surface of the semiconductor wafer to form a rim having a uniform width, as in step S2 described above, and then fixing the reinforcement member 4 to the rim.

In the dicing process, the wafer circumference to which the reinforcement member 4 is fixed is cut with a blade, and then the central portion 2 is diced so that the plurality of semiconductor elements are separated into individual pieces.

### Fifth Embodiment

Next, a fifth embodiment will be described. In the fifth embodiment, the thickness of the reinforcement member is changed in the circumferential direction, the reinforcement member being fixed to the wafer circumference (circumferential edge portion of the semiconductor wafer). Thereby, a rim is formed that has a rigidity in the Y-axis direction that is higher than a rigidity in the X-axis direction. The fifth embodiment will be described below, focusing on the differences from the fourth embodiment.

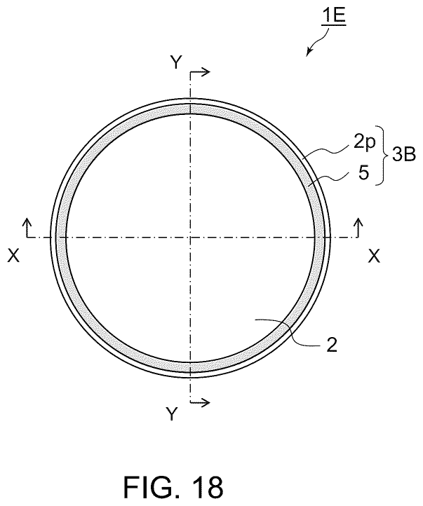

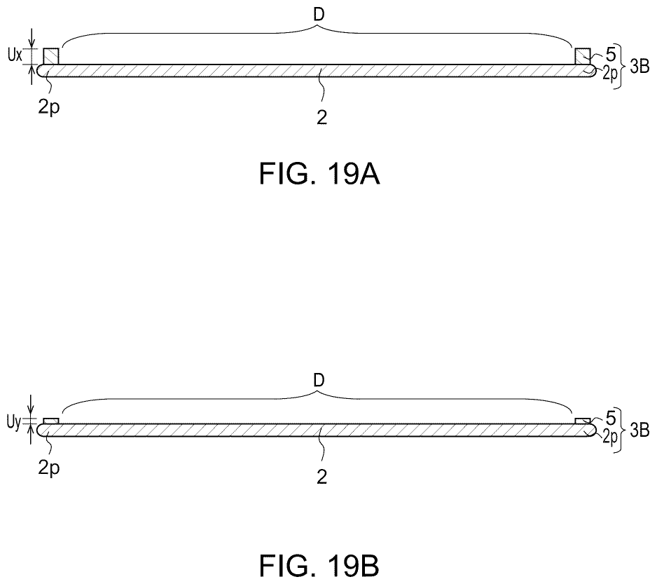

A semiconductor device 1E according to the fifth embodiment will be described with reference to FIGS. 18, 19A, and 19B. FIG. 18 is a plan view of the semiconductor device 1E. FIG. 19A is a cross sectional view taken along a line X-X in FIG. 18, and FIG. 19B is a cross sectional view taken along a line Y-Y in FIG. 18. Note that a plurality of semiconductor elements 10 are not shown in FIG. 18.

The semiconductor device 1E includes a central portion 2 including a device region D in which a plurality of semiconductor elements are formed, and a rim 3B. The rim 3B includes a wafer circumference 2p surrounding the central portion 2, and a reinforcement member 5 fixed onto the wafer circumference 2p.

The reinforcement member 5 is a ring-shaped member having a thickness in the X-axis direction (thickness at the portion intersecting with the X-axis) that is greater than a thickness in the Y-axis direction (thickness at the portion intersecting with the Y-axis). The material of the reinforcement member 5 is not particularly limited, but may be, for example, glass, resin, or metal.

The reinforcement member 5 is fixed to the wafer circumference 2p with an adhesive. The type of adhesive is the same as that described in the fourth embodiment.

As described above, in the fifth embodiment, the reinforcement member 5, which has different thicknesses in the X-axis direction and the Y-axis direction, is provided on the wafer circumference 2p, thereby forming a rim 3B having a rigidity in the Y-axis direction that is higher than a rigidity in the X-axis direction. Note that the reinforcement member 5 is not limited to being fixed to the wafer circumference 2p having the same thickness as the central portion 2. In other words, the reinforcement member 5 may be fixed to the wafer circumference that is thicker than the central portion 2, which is formed by grinding the back surface of the semiconductor wafer, thereby forming the rim 3B of this embodiment.

### Method of Forming the Rim According to the Semiconductor Device 1E

The following describes an example of a method of manufacturing the rim 3B according to the fifth embodiment.

First, the back surface of the semiconductor wafer on which a plurality of semiconductor elements are formed is ground over its entire surface. Then, the reinforcement member 5 is fixed to the wafer circumference 2p using an adhesive or the like. This forms a rim having a rigidity in the Y-axis direction that is higher than a rigidity in the X-axis direction.

Note that the wafer circumference 2p described in the fourth and fifth embodiments does not have to be the same thickness as the central portion 2. For example, there may be a way of forming a provisional rim that is thicker than the central portion, as in step S2 described above, and then fixing the reinforcement member 5 to the provisional rim, thereby forming a rim.

According to at least one of the embodiments described above, it is possible to prevent a semiconductor wafer in which a plurality of semiconductor elements are formed from warping in a specific direction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming a plurality of semiconductor elements in a device region of a first main surface of a semiconductor wafer; and
forming a rim on the semiconductor wafer, the rim surrounding the plurality of semiconductor elements and having a rigidity in a Y-axis direction that is higher than a rigidity in an X-axis direction if a first warpage amount of the semiconductor wafer in the X-axis direction is measured or estimated to be smaller than a second warpage amount of the semiconductor wafer in the Y-axis direction.

2. The method of manufacturing a semiconductor device according to claim 1, wherein a region of a second main surface of the semiconductor wafer is ground, thereby forming the rim having a width in the X-axis direction that is greater than a width in the Y-axis direction, the region corresponding to a portion where the device region is formed on the first main surface.

3. The method of manufacturing a semiconductor device according to claim 1, wherein a region of a second main surface of the semiconductor wafer is ground, thereby forming the rim including a uniform rim and a slope, the region including an area corresponding to a portion where the device region is formed on the first main surface, the uniform rim having a uniform width, the slope having a width in the X-axis direction that is greater than a width in the Y-axis direction.

4. The method of manufacturing a semiconductor device according to claim 1, wherein
a provisional rim is formed by grinding a region of a second main surface of the semiconductor wafer, the region corresponding to a portion where the device region is formed on the first main surface, and
an upper surface of the provisional rim is ground, thereby forming the rim having a thickness at a portion intersecting with an X-axis that is greater than a thickness at a portion intersecting with a Y-axis.

5. The method of manufacturing a semiconductor device according to claim 1, wherein a reinforcement member having a rigidity in the Y-axis direction that is greater than a rigidity in the X-axis direction is fixed to a circumference of the semiconductor wafer, thereby forming the rim.

6. The method of manufacturing a semiconductor device according to claim 5, wherein the reinforcement member has a width in the X-axis direction that is greater than a width in the Y-axis direction.

7. The method of manufacturing a semiconductor device according to claim 5, wherein the reinforcement member has a thickness at a portion intersecting with an X-axis that is greater than a thickness at a portion intersecting with a Y-axis.

8. The method of manufacturing a semiconductor device according to claim 1, wherein the plurality of semiconductor elements each have a trench structure extending in the X-axis direction.

9. A semiconductor device comprising:
a central portion including a device region in which a plurality of semiconductor elements are formed; and
a rim, thicker than the central portion, configured to surround the central portion,
wherein a width of the rim in an X-axis direction is greater than a width of the rim in a Y-axis direction.

10. The semiconductor device according to claim 9, wherein the rim is configured integrally with the central portion.

11. The semiconductor device according to claim 10, wherein an inner edge shape of the rim is an ellipse, an oval, or an egg shape.

12. The semiconductor device according to claim 10, wherein the rim has a uniform rim having a uniform width, and a slope that is provided inside the uniform rim and that has a width in the X-axis direction that is greater than a width in the Y-axis direction.

13. The semiconductor device according to claim 12, wherein an inner edge shape of the slope is an ellipse, an oval, or an egg shape.

14. The semiconductor device according to claim 9, wherein the rim includes a reinforcement member that is fixed to a wafer circumference surrounding the central portion and that has a width in the X-axis direction that is greater than a width in the Y-axis direction.

15. The semiconductor device according to claim 14, wherein an inner edge shape of the reinforcement member is an ellipse, an oval or an egg shape.

16. The semiconductor device according to claim 9, wherein the plurality of semiconductor elements each have a trench structure extending in the X-axis direction.

17. A semiconductor device comprising:
a central portion including a device region in which a plurality of semiconductor elements are formed; and
a rim, thicker than the central portion, configured to surround the central portion,
wherein the rim has a thickness at a portion intersecting with an X-axis that is greater than a thickness at a portion intersecting with a Y-axis.

18. The semiconductor device according to claim 17, wherein the rim is configured integrally with the central portion.

19. The semiconductor device according to claim 17, wherein the rim includes a reinforcement member that is fixed to a wafer circumference surrounding the central portion and that has a thickness at a portion intersecting with the X-axis that is greater than a thickness at a portion intersecting with the Y-axis.

20. The semiconductor device according to claim 17, wherein the plurality of semiconductor elements each have a trench structure extending in an X-axis direction.
